(19) United States
(12) Patent Application Publication
(10) Pub. No.: US 2008/0303177 A1
(43) Pub. Date: Dec. 11, 2008

(54) BONDING PAD STRUCTURE

(75) Inventors: Ping-Chang Wu, Hsinchu County (TW); Chieh-Ching Huang, Miaoli County (TW); Kuang-Hui Tang, Kaohsiung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/759,003

(22) Filed: Jun. 6, 2007

(51) Int. Cl. H01L 23/52

(52) U.S. Cl. 257/786; 257/774; 257/E23.141

(57) ABSTRACT

A bonding pad structure including a bonding pad and a passivation layer is described. The bonding pad is disposed on a chip. The passivation layer covers the bonding pad. In addition, the passivation layer has a first opening exposing a bonding region of the bonding pad and a second opening exposing a probing region of the bonding pad, respectively.

### BACKGROUND OF THE INVENTION

1. Field of the Invention

The present invention relates to a semiconductor package structure, and more particularly to a bonding pad structure.

2. Description of Related Art

In the semiconductor industry, the fabrication of an integrated circuit (IC) can be roughly classified into three main stages: a silicon chip fabrication stage, an IC fabrication stage and an IC packaging stage. The IC packaging stage is the final stage of manufacturing an IC product. The packaging is aimed at providing the chip an electrical connection to a printed circuit board (PCB) or other devices and protecting the chip.

After the semiconductor manufacturing process is completed, the bare chip is then made by sawing a wafer. Generally, bonding pads formed on the chip are employed as testing points for chip inspection and as connection terminals between the chip and other devices. In order to connect the chips and other devices, a bonding medium such as a wirebond or a solder bump is often adopted to connect the bonding pads and wires.

FIG. 1 is a schematic view of a conventional package structure.

Referring to FIG. 1, a bonding pad 102 is disposed on a chip 100. A passivation layer 104 covers the bonding pad 102 and has an opening 106 exposing the bonding pad 102. A bonding medium 108 is disposed on the bonding pad 102 exposed by the opening 106. A final testing process must be performed after the packaging is completed. Said final testing process can be performed before the bonding pad 102 is connected to the bonding medium 108 or after the bonding medium 108 is formed. If the testing process is implemented after the formation of the bonding medium 108, a probe may directly contact the bonding medium 108 to which a tip of the probe may cause a damage. Besides, an imperfect contact between the sharp probe and the ball-shaped bonding medium 108 easily results in an over-kill during the testing process. However, if the testing process is carried out before the formation of the bonding medium 108, it is unlikely to detect a connection error between the bonding medium 108 and the bonding pad 102. Moreover, the sharp probe may make a probe mark 110 on the bonding pad 102, adversely affecting the formation of the bonding medium 108 on the bonding pad 102.

Furthermore, in the conventional semiconductor manufacturing process, no other circuit designs but a metallic interconnect connected by the bonding pad is disposed around the bonding pad. In other words, only an electrical signal exists around the bonding pad. However, with an advancement of the semiconductor manufacturing process and miniaturization of semiconductor devices, it is imperative to proceed to the circuit design with -full utilization of space around the bonding pad.

### SUMMARY OF THE INVENTION

In view of the foregoing, the present invention is directed to a bonding pad structure capable of improving a connection between a bonding medium and the bonding pad.

The present invention is further directed to a bonding pad structure able to reduce operational errors during a probe inspection.

The present invention provides a bonding pad structure including a bonding pad and a passivation layer. The bonding pad is disposed on a chip. The passivation layer covers the bonding pad. In addition, the passivation layer has a first opening exposing a bonding region of the bonding pad and a second opening exposing a probing region of the bonding pad, respectively.

According to one embodiment of the present invention, the material of the bonding pad includes aluminum.

According to one embodiment of the present invention, the material of the passivation layer includes silicon nitride.

According to one embodiment of the present invention, the first opening and the second opening are in different shapes.

According to one embodiment of the present invention, the first opening and the second opening are in different sizes.

According to one embodiment of the present invention, the chip further includes a supporting metal layer disposed in a dielectric layer of the chip below the bonding region. The supporting metal layer is electrically connected to the bonding pad.

According to one embodiment of the present invention, the material of the dielectric layer includes silicon oxide.

According to one embodiment of the present invention, the material of the supporting metal layer includes copper.

According to one embodiment of the present invention, the supporting metal layer includes a metallic interconnect.

According to one embodiment of the present invention, an area of the supporting metal layer right below the bonding region exceeds 75% of the area of the bonding region.

According to one embodiment of the present invention, the supporting metal layer includes a plurality of metallic patterns.

According to one embodiment of the present invention, an area of the supporting metal layer right below the bonding region exceeds 75% of the area of the bonding region.

The present invention further provides a bonding pad structure including a bonding pad and a passivation layer. The bonding pad is disposed on the chip and includes a bonding pattern and a probing pattern. The probing pattern is electrically connected to the bonding pattern. The passivation layer covers the bonding pad. In addition, the passivation layer has a first opening exposing a bonding pattern of the bonding pad and a second opening exposing a probing pattern of the bonding pad, respectively.

According to another embodiment of the present invention, the material of the bonding pad includes aluminum.

According to another embodiment of the present invention, the material of the passivation layer includes silicon nitride.

According to another embodiment of the present invention, the first opening and the second opening are in different shapes.

According to another embodiment of the present invention, the first opening and the second opening are in different sizes.

According to another embodiment of the present invention, the chip further includes a supporting metal layer disposed in a dielectric layer of the chip below the bonding region. The supporting metal layer is electrically connected to the bonding pattern and the probing pattern through a plurality of vias.

According to another embodiment of the present invention, the material of the dielectric layer includes silicon oxide.

According to another embodiment of the present invention, the material of the vias includes aluminum.

According to another embodiment of the present invention, the material of the supporting metal layer includes copper.

According to another embodiment of the present invention, the supporting metal layer includes a metallic interconnect.

According to another embodiment of the present invention, an area of the supporting metal layer right below the bonding pattern exceeds 75% of the area of the bonding pattern.

According to another embodiment of the present invention, the supporting metal layer includes a plurality of metallic patterns.

According to another embodiment of the present invention, an area of the supporting metal layer right below the bonding pattern exceeds 75% of the area of the bonding pattern.

The present invention further provides a bonding pad structure including a bonding pad, a passivation layer and two strip-shaped vias. The bonding pad is disposed on a chip. The passivation layer covers the bonding pad and has an opening exposing a part of the bonding pad. The strip-shaped vias are disposed in the chip below the passivation layer and are electrically connected to the bonding pad. Besides, the strip-shaped vias are located at respective sides of the opening. A length of the strip-shaped vias is less than a length of two sides of the opening, and the opening is divided into a bonding region and a probing region by the strip-shaped vias. One of the bonding region and the probing region is located between the strip-shaped vias.

According to still another embodiment of the present invention, the material of the bonding pad includes aluminum.

According to still another embodiment of the present invention, the material of the passivation layer includes silicon nitride.

According to still another embodiment of the present invention, the material of the strip-shaped vias includes aluminum.

Based on the above, the bonding region of the bonding pad and the probing region thereof are divided in the bonding pad structure provided by the present invention. Thereby, even though a probe may make probe marks after the probe is used for chip inspection, the probe marks merely exist in the probing region, posing no influence on a connection between the bonding medium and the bonding pad. In addition, it is likely for technicians to determine the bonding pad region to be contacted by the probe, reducing the operational errors.

On the other hand, the supporting metal layer is disposed below the bonding region of the bonding pad structure provided by the present invention. Thereby, stress generated through the connection between the bonding medium and the bonding pad may be resisted, damages to the products can be avoided, and yield of the products is further improved. Moreover, only a single-layered supporting metal layer below the bonding pad structure is required to achieve the supporting effect, and thus other spaces below the bonding pad structure can be used for other circuit designs. The fall utilization of space further improves the level of integration of the products.

In order to the make the aforementioned and other objects, features and advantages of the present invention comprehensible, several embodiments accompanied with figures are described in detail below.

### BRIEF DESCRIPTION OF THE DRAWINGS

FIG. 1 is a schematic view of a conventional package structure.

FIG. 2 is a top view of a chip according to an embodiment of the present invention.

FIG. 3 is an enlarged partial view of the bonding pad structure in FIG. 2.

FIG. 4 is a top view of a bonding pad structure according to another embodiment of the present invention.

FIG. 5 is a cross-sectional view taken along line A-A′ of FIG. 3 according to an embodiment of the present invention.

FIG. 6 is a cross-sectional view taken along line A-A′ of FIG. 3 according to another embodiment of the present invention.

FIG. 7 is a top view of a bonding pad structure according to still another embodiment of the present invention.

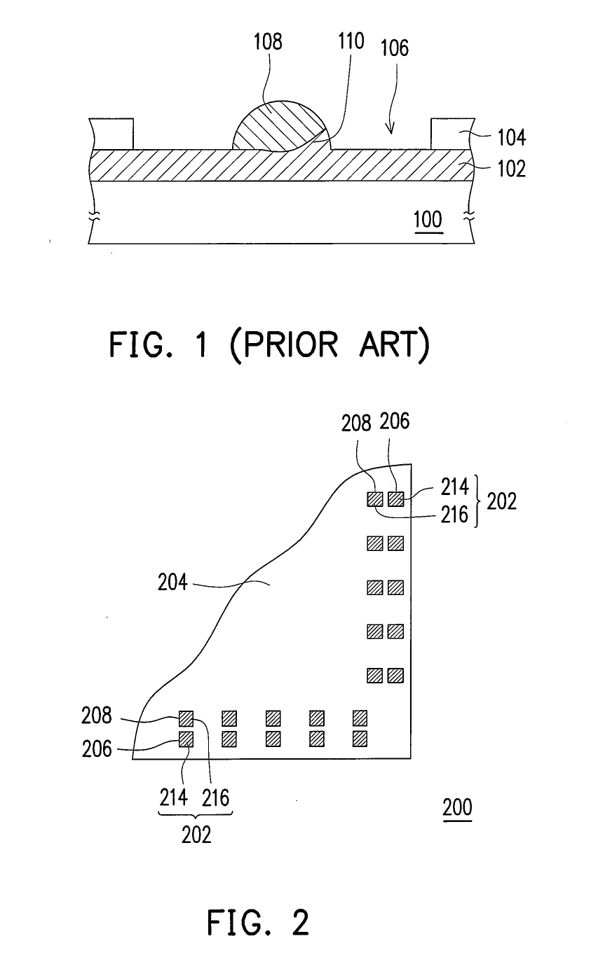

### DESCRIPTION OF EMBODIMENTS

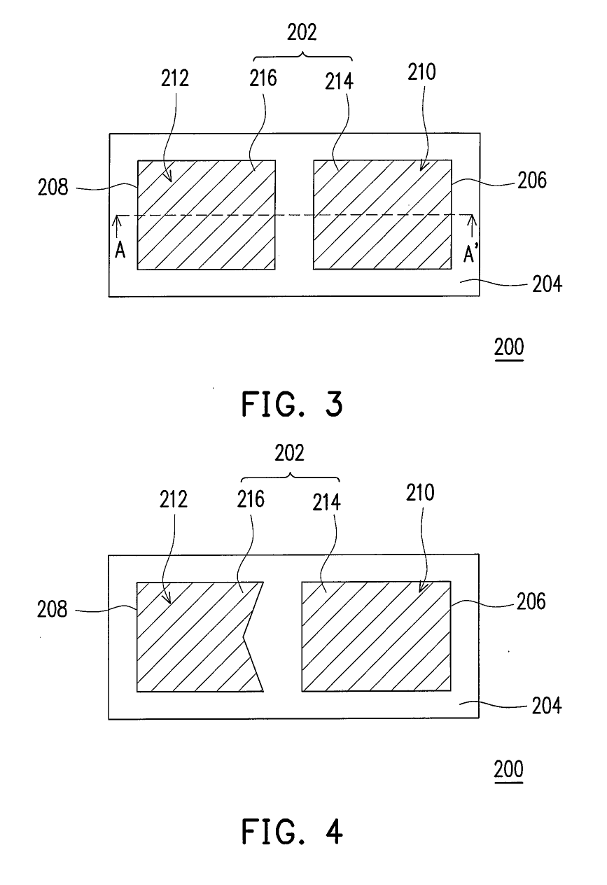

FIG. 2 is a top view of a chip according to an embodiment of the present invention. FIG. 3 is an enlarged partial view of the bonding pad structure in FIG. 2. FIG. 4 is a top view of a bonding pad structure according to another embodiment of the present invention.

First, referring to FIGS. 2 and 3 together, the bonding pad structure has a bonding pad 202 and a passivation layer 204. The bonding pad 202 is disposed on a chip 200. The material of the bonding pad 202 is aluminum, for example, and the material of the passivation layer 204 is, for example, silicon nitride.

The passivation layer 204 covers the bonding pad 202 and has an opening 206 exposing a bonding region 210 of the bonding pad 202 and an opening 208 exposing a probing region 212 of the bonding pad 202, respectively. The bonding region 210 is, for example, disposed outside the chip 200, while the probing region 212 is, for example, disposed inside the chip 200. However, the present invention is not limited to said dispositions. The bonding pad 202 exposed by the bonding region 210 is, for example, used as a bonding pattern 214 to connect a bonding medium, while the bonding pad 202 exposed by the probing region 212 is, for example, utilized as a probing pattern 216 for a probe inspection.

It should be noted that the opening 206 and the opening 208 are in the same shape and size in the present embodiment. Nevertheless, the openings 206 and 208 may be in different shapes and sizes in other embodiments. Those of ordinary skill in the art can make necessary adjustment based on actual demands. For example, referring to FIG. 4, the opening 206 may be rectangular, and the opening 208 may be a pentagon with indention. An area of the opening 206 exceeds that of the opening 208, for example.

According to the above embodiment, the bonding pad structure can be divided into the bonding region 210 and the probing region 212 through the opening 206 and the opening 208. Since the probe inspection is performed in the probing region 212, even though the probe marks on the bonding pad 202 are caused by the probe, the probe marks merely exist in the probing region 212, posing no influence on a connection between the bonding medium and the bonding pad 202 in the bonding region 210, and thus a connection between the bonding medium and the bonding pad 202 can be improved.

On the other hand, the bonding pad 202 is defined as the bonding region 210 and the probing region 212. Accordingly, it is likely for the technicians to detect the bonding pad region to be contacted by the probe by being informed of whether the bonding region 210 or the probing region 212 is disposed inside the chip 200, reducing the operational errors. Moreover, the errors caused by the technicians may be further reduced through adjusting the designs of the shape and the size of the openings 206 and 208.

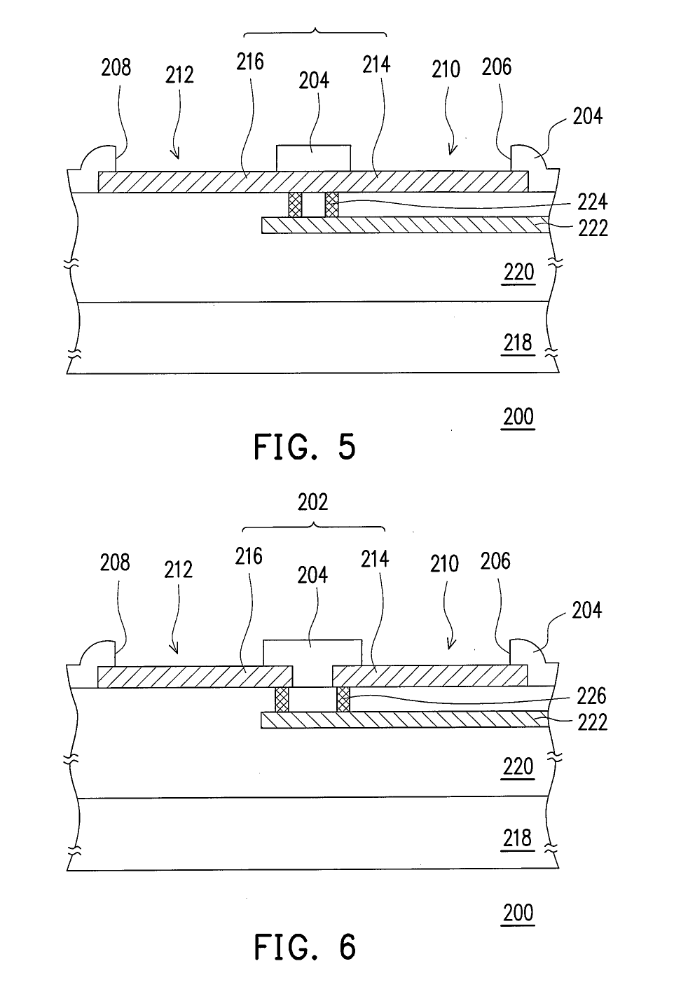

FIG. 5 is a cross-sectional view taken along line A-A′ of FIG. 3 according to an embodiment of the present invention.

Referring to FIG. 5, a bonding pad structure includes a bonding pad 202 and a passivation layer 204. The bonding pad 202 is disposed on a chip 200. The passivation layer 204 covers the bonding pad 202 and has an opening 206 exposing a bonding region 210 of the bonding pad 202 and an opening 208 exposing a probing region 212 of the bonding pad 202, respectively. Here, the bonding region 210 exposes a bonding pattern 214, while the probing region 212 exposes a probing pattern 216. According to the present embodiment, the bonding pattern 214 and the probing pattern 216 together constructing the bonding pad 202 are, for example, formed as a whole.

The chip 200 includes a substrate 218, a dielectric layer 220 and a supporting metal layer 222. The substrate 218 is, for example, a silicon substrate. The material of the dielectric layer 220 is, for example, silicon oxide, and the material of the supporting metal layer 222 is, for example, copper.

The supporting metal layer 222 is disposed in the dielectric layer 220 below the bonding region 210 and is electrically connected to the bonding pad 202. In another embodiment, however, the supporting metal layer 222 may extend below the probing region 212. The supporting metal layer 222 is a metallic interconnect, for example, and the supporting metal layer 222 is electrically connected to the bonding pad 202 through vias 224, for example. The vias 224 are, for example, disposed in the dielectric layer 220 below the passivation layer 204 between the bonding region 210 and the probing region 212, for example. In addition, the vias 224 and the bonding pad 202 may be formed simultaneously. The material of the vias 224 is, for example, aluminum.

It should be noted that on the premise that the supporting metal layer 222 below the bonding region 210 is capable of providing sufficient support to resist stress generated through connection between the bonding medium and the bonding pad 202, the supporting metal layer 222 may be formed by a complete metal layer or by a plurality of metallic patterns. For example, an area of the supporting metal layer 222 right below the bonding region 210 exceeds 75% of the area of the bonding region 210, so as to provide desired support.

FIG. 6 is a cross-sectional view taken along line A-A′ of FIG. 3 according to another embodiment of the present invention.

Referring to FIG. 6, the difference between the embodiment depicted in FIG. 6 and that depicted in FIG. 5 lies in that the bonding pad 202 is formed by the bonding pattern 214 and the probing pattern 216. The bonding pattern 214 and the probing pattern 216 are separated from and disposed next to each other. The probing pattern 216 and the bonding pattern 214 are electrically connected to the supporting metal layer 222 through vias 226, for example. The vias 226 are, for example, disposed in the dielectric layer 220 below the passivation layer 204 between the bonding region 210 and the probing region 212, for example. The material of the vias 226 is, for example, aluminum. The arrangements, materials and functions of other components in FIG. 6 are approximately identical to those in FIG. 5, and thus no further description is provided hereinafter.

Based on the above, since the supporting metal layer 222 is able to prevent stress from generating through the connection between the bonding medium and the bonding pad 202, damages to the products can be avoided, and yield of the products is further improved. Besides, only a single-layered supporting metal layer 222 below the bonding pad structure is sufficient to prevent stress from generating through the connection between the bonding medium and the bonding pad 202. Thus, other spaces below the bonding pad structure can be used for other circuit designs, and the full utilization of space further improves the level of integration of the products.

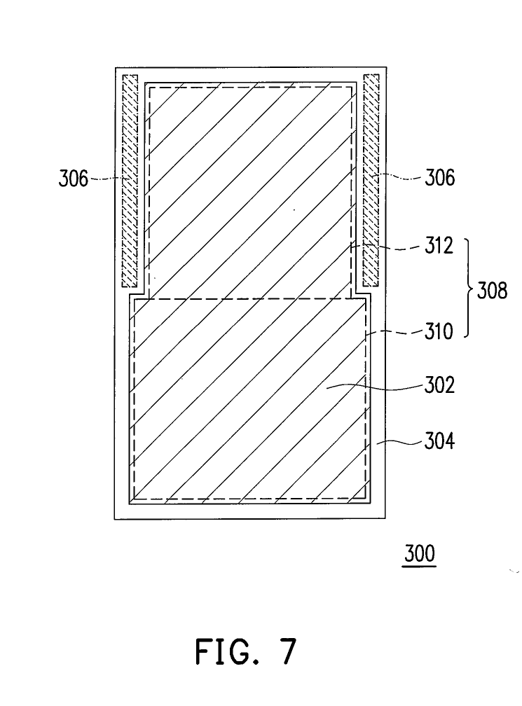

FIG. 7 is a top view of a bonding pad structure according to still another embodiment of the present invention.

Referring to FIG. 7, the bonding pad structure includes a bonding pad 302, a passivation layer 304 and strip-shaped vias 306. The bonding pad 302 is disposed on a chip 300. The material of the bonding pad 302 is aluminum, for example.

The passivation layer 304 covers the bonding pad 302 and has an opening 308 exposing a part of the bonding pad 302. The material of the passivation layer 304 is, for example, silicon nitride.

The strip-shaped vias 306 are disposed in the chip 300 below the passivation layer 304 and are electrically connected to the bonding pad 302. Moreover, the strip-shaped vias 306 are disposed at respective sides of the opening 308. The material of the strip-shaped vias 306 is, for example, aluminum. Here, a length of the strip-shaped vias 306 is less than a length of two sides of the opening 308. The strip-shaped vias 306 are taken to mark and divide the opening 308 into a bonding region 310 and a probing region 312, and the probing region 312 is located between the strip-shaped vias 306. In addition, people skilled in the art may adjust the length of the strip-shaped vias 306, the size of the bonding region 310, and the size of the probing region 312 based on actual demands.

Even though the probing region 312 located between the strip-shaped vias 306 is taken for an example in the present embodiment, the region positioned between the strip-shaped vias 306 can be designed as other specific regions. According to other embodiments, the region positioned between the strip-shaped vias may also be the bonding region.

It can be known from the above embodiment that the bonding pad structure may define the bonding region 310 and the probing region 312 by using the strip-shaped vias 306 as markings. Accordingly, even though a probe leads to probe marks on the bonding pad 302, the marks merely exist in the probing region 312, thus improving a connection between the bonding medium and the bonding pad 302.

Likewise, the positions of the bonding region 310 and the probing region 312 may be identified through the strip-shaped vias 306. Therefore, as long as the region between the strip-shaped vias 306 is defined as the bonding region 310 or the probing region 312, it is likely for the technicians to detect the region to be contacted by the probe, reducing possible operational errors.

In summary, the present invention has at least the following advantages:

The bonding pad structure provided by the present invention is capable of improving the connection between the bonding medium and the bonding pad.

With the bonding pad structure provided by the present invention, it is likely for the technicians to identify the bonding pad region to be contacted by the probe, reducing the operational errors.

The supporting metal layer is disposed below the bonding region in the bonding pad structure provided by the present invention. Thereby, stress generated through the connection between the bonding medium and the bonding pad may be resisted, and yield of the products is further improved.

In the bonding pad structure of the present invention, other spaces below the bonding pad structure can be used for other circuit designs. The full utilization of space further improves the level of integration of the products.

1. A bonding pad structure, comprising:
a bonding pad disposed on a chip; and
a passivation layer covering the bonding pad and having a first opening and a second opening, wherein a shape of one of the first opening and the second has indention and the first opening and the second opening expose a bonding region and a probing region of the bonding pad, respectively.

2. The bonding pad structure of claim 1, wherein the material of the bonding pad comprises aluminum.

3. The bonding pad structure of claim 1, wherein the material of the passivation layer comprises silicon nitride.

4. The bonding pad structure of claim 1, wherein the first opening and the second opening are in different shapes.

5. The bonding pad structure of claim 1, wherein the first opening and the second opening are in different sizes.

6. The bonding pad structure of claim 1, the chip further comprising a supporting metal layer disposed in a dielectric layer of the chip below the bonding region, wherein the supporting metal layer is electrically connected to the bonding pad.

7. The bonding pad structure of claim 6, wherein the material of the dielectric layer comprises silicon oxide.

8. The bonding pad structure of claim 6, wherein the material of the supporting metal layer comprises copper.

9. The bonding pad structure of claim 6, wherein the supporting metal layer comprises a metallic interconnect.

10. The bonding pad structure of claim 6, wherein an area of the supporting metal layer right below the bonding region exceeds 75% of the area of the bonding region.

11. The bonding pad structure of claim 6, wherein the supporting metal layer comprises a plurality of metallic patterns.

12. The bonding pad structure of claim 9, wherein an area of the supporting metal layer right below the bonding region exceeds 75% of the area of the bonding region.

13. A bonding pad structure, comprising:
a bonding pad disposed on a chip, the bonding pad comprising:
a bonding pattern; and
a probing pattern electrically connected to the bonding pattern through vias; and
a passivation layer covering the bonding pad and having a first opening and a second opening, wherein the first opening and the second opening expose the bonding pattern and the probing pattern of the bonding pad, respectively.

14. The bonding pad structure of claim 13, wherein the material of the bonding pad comprises aluminum.

15. The bonding pad structure of claim 13, wherein the material of the passivation layer comprises silicon nitride.

16. The bonding pad structure of claim 13, wherein the first opening and the second opening are in different shapes.

17. The bonding pad structure of claim 13, wherein the first opening and the second opening are in different sizes.

18. The bonding pad structure of claim 13, the chip further comprising a supporting metal layer disposed in a dielectric layer of the chip below the bonding region, wherein the supporting metal layer is electrically connected to the bonding pattern and the probing pattern through a plurality of vias.

19. The bonding pad structure of claim 18, wherein the material of the dielectric layer comprises silicon oxide.

20. The bonding pad structure of claim 18, wherein the material of the vias comprises aluminum.

21. The bonding pad structure of claim 18, wherein the material of the supporting metal layer comprises copper.

22. The bonding pad structure of claim 18, wherein the supporting metal layer comprises a metallic interconnect.

23. The bonding pad structure of claim 18, wherein an area of the supporting metal layer right below the bonding pattern exceeds 75% of the area of the bonding pattern.

24. The bonding pad structure of claim 18, wherein the supporting metal layer comprises a plurality of metallic patterns.

25. The bonding pad structure of claim 24, wherein an area of the supporting metal layer right below the bonding pattern exceeds 75% of the area of the bonding pattern.

26. A bonding pad structure, comprising:
a bonding pad disposed on a chip; and
a passivation layer covering the bonding pad and having an opening exposing a part of the bonding pad; and
two strip-shaped vias disposed in the chip below the passivation layer and electrically connected to the bonding pad, the strip-shaped vias being located at respective sides of the opening, wherein a length of the strip-shaped vias is less than a length of two sides of the opening, the opening is divided into a bonding region and a probing region by the strip-shaped vias, and one of the bonding region and the probing region is located between the strip-shaped vias.

27. The bonding pad structure of claim 26, wherein the material of the bonding pad comprises aluminum.

28. The bonding pad structure of claim 26, wherein the material of the passivation layer comprises silicon nitride.

29. The bonding pad structure of claim 26, wherein the material of the strip-shaped vias comprises aluminum.
